(19) United States
(12) Patent Application Publication
(10) Pub. No.: US 2026/0262231 A1
(43) Pub. Date: Sep. 3, 2026

(54) SEMICONDUCTOR DEVICE MANUFACTURING METHOD AND SEMICONDUCTOR DEVICE

(71) Applicant: Kioxia Corporation, Tokyo (JP)

(72) Inventors: Junya WADA, Yokkaichi Mie (JP); Susumu HASHIMOTO, Kuwana Mie (JP); Yuya NAITO, Yokkaichi Mie (JP); Hiroshi ITOKAWA, Kuwana Mie (JP); Masayoshi TAGAMI, Kuwana Mie (JP)

(73) Assignee: Kioxia Corporation, Tokyo (JP)

(21) Appl. No.: 19/246,314

(22) Filed: Jun. 23, 2025

(30) Foreign Application Priority Data
Feb. 28, 2025 (JP) 2025-032346

(51) Int. Cl. H10B 80/00; H01L 23/00; H01L 25/00; H01L 25/065; H01L 25/18

(52) U.S. Cl. CPC H10B 80/00; H10W 90/00; H10W 80/211; H10W 80/312; H10W 80/327; H10W 90/792

(57) ABSTRACT

A semiconductor device manufacturing method of embodiments includes: forming, for a stacked body having a first substrate, a first layer, a second layer, a third layer, and a fifth layer, an opening penetrating the third layer, the second layer, and the first layer to reach the fifth layer; forming a columnar portion and a fourth layer; forming a sixth layer on the fourth layer; bonding the sixth layer to a seventh layer; emitting the laser light onto the second surface; and peeling off the first substrate.

### CROSS-REFERENCE TO RELATED APPLICATION

This application is based upon and claims the benefit of priority from Japanese Patent Application No. 2025-32346, filed on Feb. 28, 2025, the entire contents of which are incorporated herein by reference.

### FIELD

Embodiments described herein relate generally to a semiconductor device manufacturing method and a semiconductor device.

### BACKGROUND

A semiconductor device and a semiconductor device manufacturing method using a bonding technique for bonding substrates together have been developed.

### BRIEF DESCRIPTION OF THE DRAWINGS

FIG. 1 is a schematic cross-sectional view of a semiconductor device according to a first embodiment;

FIG. 2 is a schematic cross-sectional view of a memory pillar of the semiconductor device according to the first embodiment;

FIG. 3-5 are schematic cross-sectional views showing a method for manufacturing the semiconductor device according to the first embodiment;

FIG. 6-10 are schematic cross-sectional views showing a method for manufacturing a main portion of the semiconductor device according to the first embodiment;

FIG. 11-15 are schematic cross-sectional views showing a method for manufacturing a main portion of a semiconductor device according to a second embodiment;

FIG. 16-18 are schematic cross-sectional views showing a method for manufacturing a main portion of a semiconductor device according to a third embodiment;

FIG. 19-24 are schematic cross-sectional views showing a method for manufacturing a main portion of a semiconductor device according to a fourth embodiment;

### DETAILED DESCRIPTION

Hereinafter, embodiments will be described with reference to the drawings. In addition, in the drawings, the same or similar elements are denoted by the same or similar reference numerals.

In this specification, in order to show the positional relationship of components and the like, the upper direction of the drawing is described as “upper” and the lower direction of the drawing is described as “lower”. In this specification, the concepts of “upper” and “lower” do not necessarily indicate the relationship with the direction of gravity.

### First Embodiment

A semiconductor device manufacturing method of embodiments includes: forming, for a stacked body having a first substrate allowing laser light to pass therethrough and the first substrate having a first surface and a second surface, a first layer provided on the first surface, a second layer provided on the first layer, the second layer having a higher absorption rate for the laser light than the first layer, and the second layer having a higher thermal conductivity than the first layer, a third layer provided on the second layer, the third layer having a lower absorption rate for the laser light than the second layer, and the third layer having a lower thermal conductivity than the second layer, and a fifth layer provided between the first layer and the first substrate and the fifth layer having an electrical conductivity, an opening penetrating the third layer, the second layer, and the first layer to reach the fifth layer; forming a columnar portion and a fourth layer, the columnar portion being provided in the opening, the columnar portion having an electrical conductivity, the fourth layer being provided on the third layer, the fourth layer being electrically connected to the columnar portion, and the fourth layer having an electrical conductivity; forming a sixth layer on the fourth layer, the sixth layer having a device, and the device being electrically connected to the fourth layer; bonding the sixth layer to a seventh layer, the seventh layer being provided on a third surface of a second substrate, the second substrate having the third surface and a fourth surface, and the seventh layer having an electrical circuit; emitting the laser light onto the second surface; and peeling off the first substrate.

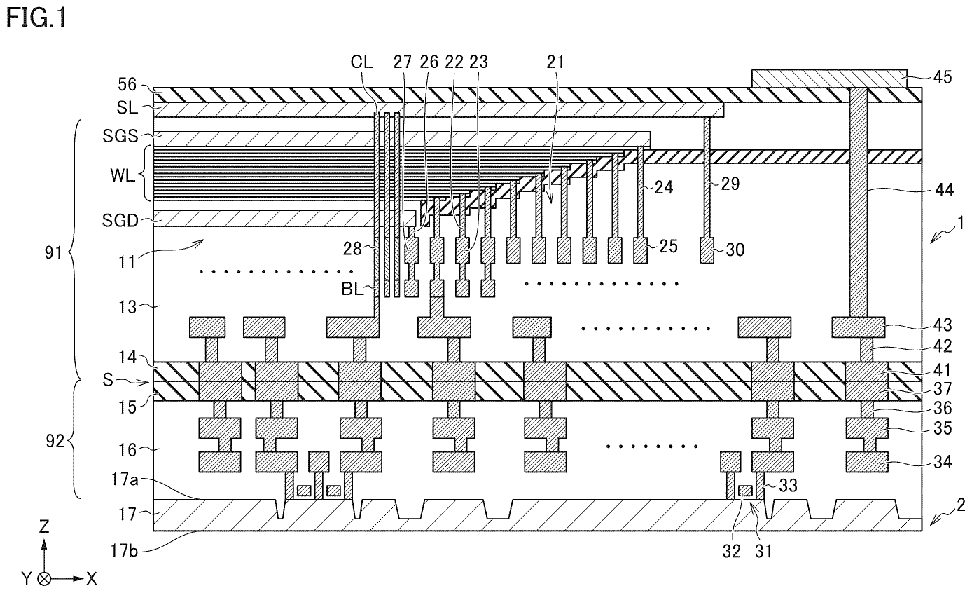

FIG. 1 is a schematic cross-sectional view of the semiconductor device of embodiments. The semiconductor device shown in FIG. 1 is a three-dimensional memory in which an array chip 1 and a circuit chip 2 are bonded together.

The array chip 1 includes a memory cell array 11 including a plurality of memory cells, a third layer 56 on the memory cell array 11, an interlayer insulating film 13 below the memory cell array 11, and an insulating film 14 below the interlayer insulating film 13. The insulating film 14 includes, for example, silicon oxide or silicon nitride. The third layer 56 will be described later.

The circuit chip 2 is provided below the array chip 1. A reference numeral S indicates a bonding surface between the array chip 1 and the circuit chip 2. The circuit chip 2 includes an insulating film 15, an interlayer insulating film 16 below the insulating film 15, and a substrate 17 (an example of a second substrate) below the interlayer insulating film 16. The insulating film 15 includes, for example, silicon oxide or silicon nitride. The substrate 17 is, for example, a semiconductor substrate such as a silicon substrate. The substrate 17 has a surface 17a (an example of a third surface) and a surface 17b (an example of a fourth surface) on a side opposite to the surface 17a.

FIG. 1 shows an X direction parallel to the surfaces (surfaces 17a and 17b) of the substrate 17, a Y direction parallel to the surfaces of the substrate 17 and crossing the X direction, and a Z direction perpendicular to the surfaces of the substrate 17 and crossing the X and Y directions.

For example, the memory cell array 11 is located above the substrate 17, and the substrate 17 is located below the memory cell array 11. The-Z direction may or may not match the direction of gravity. In addition, the X and Y directions are also parallel to the surfaces (surfaces 18a and 18b) of a substrate 18 described later, and the Z direction is also perpendicular to the surfaces of the substrate 18.

The array chip 1 includes, as electrode layers in the memory cell array 11, a plurality of word lines WL, a source side selection gate SGS, a drain side selection gate SGD, and a source line SL (an example of a fourth layer). FIG. 1 shows a staircase structure 21 of the memory cell array 11.

As shown in FIG. 1, each word line WL is electrically connected to a word wiring layer 23 through a contact plug 22, and the source side selection gate SGS is electrically connected to a source side selection gate wiring layer 25 through a contact plug 24. In addition, the drain side selection gate SGD is electrically connected to a drain side selection gate wiring layer 27 through a contact plug 26, and the source line SL is electrically connected to a source wiring layer 30 through a contact plug 29. A memory pillar CL that penetrates the word line WL, the source side selection gate SGS, and the drain side selection gate SGD is electrically connected to a bit line BL through a plug 28, and is also electrically connected to the source line SL.

The circuit chip 2 includes a plurality of transistors 31. Each transistor 31 includes a gate electrode 32 provided on the substrate 17 with a gate insulating film interposed therebetween and a source diffusion layer and a drain diffusion layer (not shown) provided in the substrate 17. The circuit chip 2 further includes a plurality of plugs 33 provided on the source diffusion layers or drain diffusion layers of the transistors 31, a wiring layer 34 provided on the plugs 33 and including a plurality of wirings, and a wiring layer 35 provided on the wiring layer 34 and including a plurality of wirings. The circuit chip 2 further includes a plurality of via plugs 36 provided on the wiring layer 35 and a plurality of metal pads 37 provided on the via plugs 36 in the insulating film 15. The metal pad 37 is, for example, a copper (Cu) layer or an aluminum (Al) layer. The circuit chip 2 functions as a control circuit (logic circuit) that controls the array chip 1. This control circuit includes the transistor 31 and the like, and is electrically connected to the metal pad 37.

The array chip 1 includes a plurality of metal pads 41 provided on the metal pads 37 in the insulating film 14, a plurality of via plugs 42 provided on the metal pads 41, and a wiring layer 43 provided on the via plugs 42 and including a plurality of wirings. Each word line WL or each bit line BL is electrically connected to a corresponding wiring in the wiring layer 43. The metal pad 41 is, for example, a Cu layer or an Al layer. The array chip 1 further includes a via plug 44 provided in the interlayer insulating film 13 or in the third layer 56 and provided on the wiring layer 43 and a metal pad 45 provided on the insulating film 13 or on the via plug 44. The metal pad 45 is, for example, a Cu layer or an Al layer, and functions as an external connection pad (bonding pad) of the semiconductor device in FIG. 1 and can be connected to a mounting board or other devices through a bonding wire, a solder ball, a metal bump, or the like.

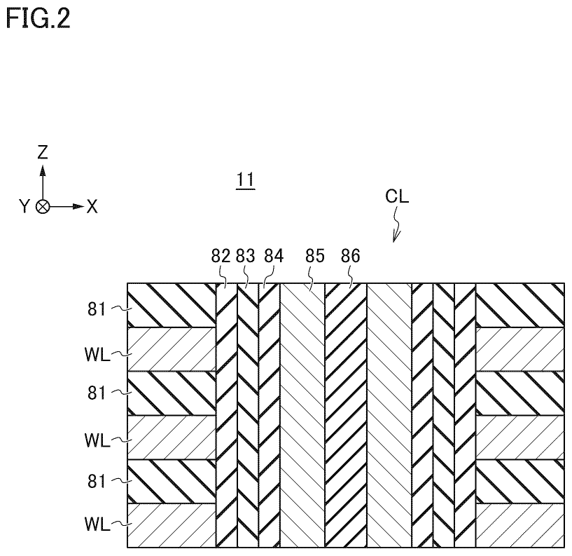

FIG. 2 is a schematic cross-sectional view of the memory pillar CL of the semiconductor device of embodiments.

As shown in FIG. 2, the memory cell array 11 includes a plurality of word lines WL and a plurality of insulating layers 81 alternately provided on the interlayer insulating film 13 (FIG. 1). The word lines WL are stacked so as to be spaced from each other in the Z direction. The word line WL includes, for example, a tungsten (W) or a molybdenum (Mo). The insulating layer 81 is, for example, a silicon oxide film.

The memory pillar CL includes a block insulating film 82, a charge storage layer 83, a tunnel insulating film 84, a channel semiconductor layer 85, and a core insulating film 86 in this order. The charge storage layer 83 is, for example, a silicon nitride film, and is formed on the side surfaces of the word lines WL and the insulating layers 81 with the block insulating film 82 interposed therebetween. The channel semiconductor layer 85 is, for example, a polysilicon layer, and is formed on the side surface of the charge storage layer 83 with the tunnel insulating film 84 interposed therebetween. The block insulating film 82, the tunnel insulating film 84, and the core insulating film 86 are, for example, silicon oxide films or metal oxide films.

In addition, although the insulating film 14 is formed on the lower surface of the interlayer insulating film 13 in FIG. 1, the insulating film 14 may be included in the interlayer insulating film 13 so as to be integrated therewith. Similarly, although the insulating film 15 is formed on the upper surface of the interlayer insulating film 16 in FIG. 1, the insulating film 15 may be included in the interlayer insulating film 16 so as to be integrated therewith.

A portion of the array chip 1 from the insulating film 14 and the metal pad 41 to the interlayer insulating film 13 below the source line SL and below the third layer 56 is a device layer 91. The device layer 91 is an example of a sixth layer having a memory cell (an example of a device). Here, the memory pillar CL included in the memory cell array 11 is electrically connected to the source line SL. Therefore, the device layer 91 having a memory cells is electrically connected to the source line SL. In addition, devices included in the device layer 91 may be other devices such as a dynamic random access memory (DRAM), a static random access memory (SRAM), a phase-change random access memory (PRAM), and a junction field effect transistor (JFET).

A portion of the circuit chip 2 from the insulating film 15 and the metal pad 37 to the interlayer insulating film 16, the transistor 31, the gate electrode 32, and the plug 33 on the substrate 17 is a circuit layer 92. The circuit layer 92 is an example of a seventh layer having an electrical circuit. The circuit layer 92 is provided on the surface 17a of the substrate 17.

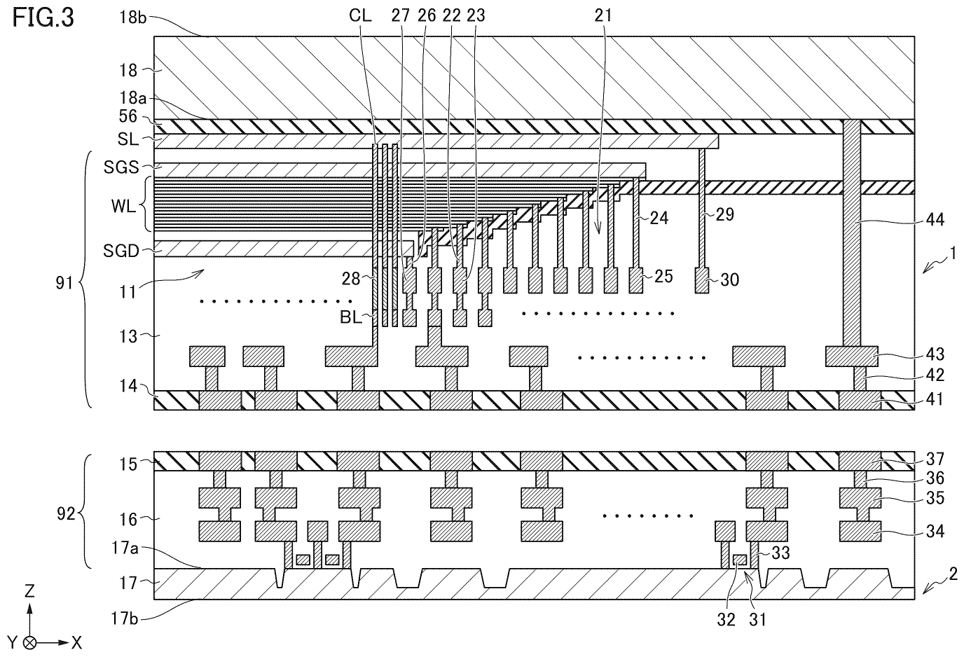

FIGS. 3 to 5 are schematic cross-sectional views showing a semiconductor device manufacturing method of embodiments.

FIG. 3 shows the array chip 1 and the circuit chip 2. The substrate 18 (an example of a first substrate) is provided on the third layer 56. The substrate 18 is, for example, a semiconductor substrate such as a silicon substrate. The substrate 18 has a surface 18a (an example of a first surface) and a surface 18b (an example of a second surface).

The transistor 31, the gate electrode 32, the plug 33, the wiring layer 34, the wiring layer 35, the via plug 36, the interlayer insulating film 16, the insulating film 15, the metal pad 37, and the like are formed on the substrate 17 to manufacture the circuit chip 2.

In addition, the memory cell array 11 and the interlayer insulating film 13 are formed on the surface 18a of the substrate 18 with the third layer 56 interposed therebetween, and the via plug 44, the wiring layer 43, the via plug 42, the insulating film 14, the metal pad 41, and the like are formed in the third layer 56 or the interlayer insulating film 13, thereby manufacturing the array chip 1.

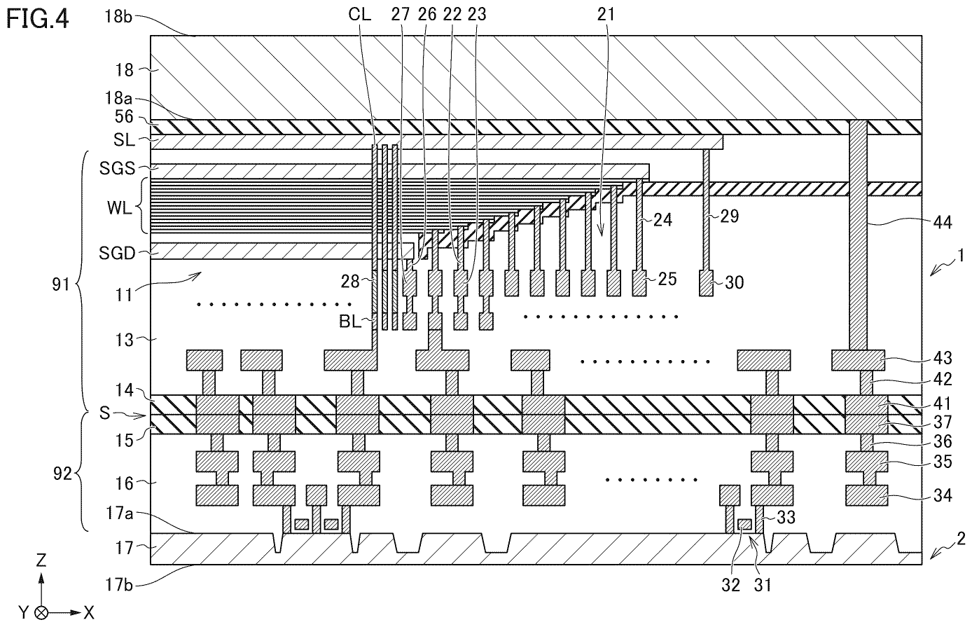

Then, the array chip 1 is bonded to the circuit chip 2 (FIG. 4). In other words, the device layer 91 and the circuit layer 92 are bonded together. Specifically, first, the array chip 1 and the circuit chip 2 are bonded together by applying mechanical pressure. Then, the array chip 1 and the circuit chip 2 are annealed at a temperature of, for example, 250° C. or more and 400° C. or less. As a result, the metal pad 41 is bonded to the metal pad 37 and electrically connected to the metal pad 37.

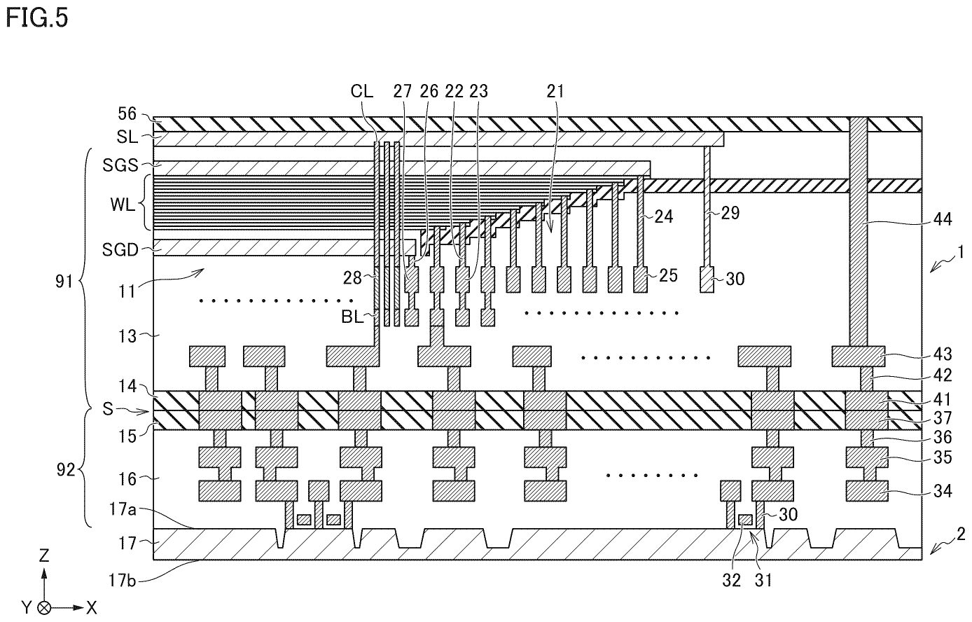

Then, the substrate 18 is removed from the array chip 1 (FIG. 5). As a result, the via plug 44 is exposed. The substrate 18 is removed, for example, by emitting laser light, which will be described later, in a direction of the device layer 91 from the surface 18b of the substrate 18. In addition, the substrate 18 may be removed by chemical mechanical polishing (CMP) or wet etching.

Then, the metal pad 45 (FIG. 1) is formed on the third layer 56 and the via plug 44 by, for example, chemical vapor deposition (CVD) and reactive ion etching (RIE), thereby obtaining the semiconductor device of embodiments.

In addition, for convenience of illustration, one array chip 1 and one circuit chip 2 are shown in FIGS. 3 to 5. However, it is preferable to use a step in which the substrate 18 having a plurality of array chips 1 and the substrate 17 having a plurality of circuit chips 2 are bonded together and then cut by dicing or the like.

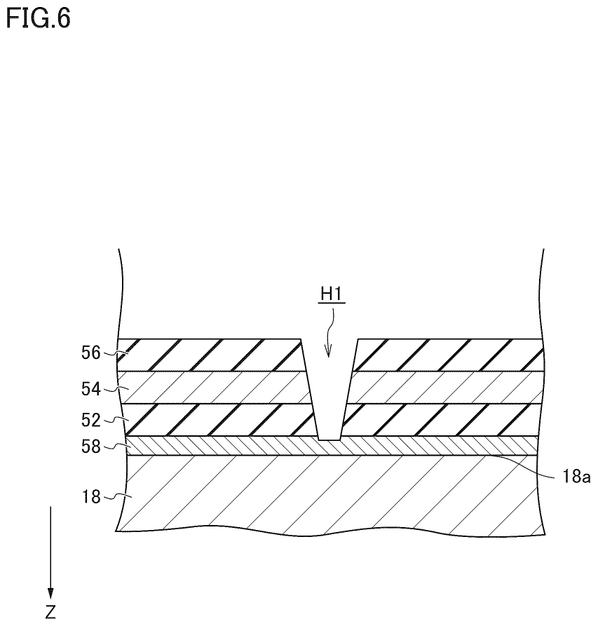

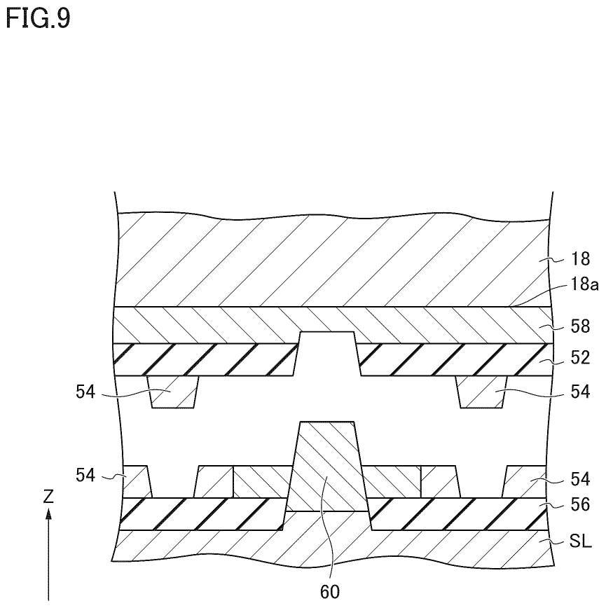

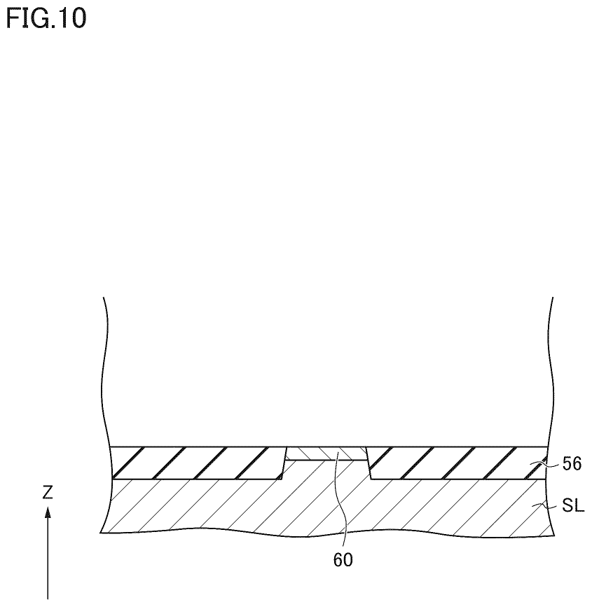

FIGS. 6 to 10 are schematic cross-sectional views showing a method for manufacturing a main portion (an example of a stacked body) of the semiconductor device of embodiments. FIGS. 6 to 10 are schematic cross-sectional views showing the periphery of the surface 18a of the substrate 18 of the semiconductor device. In addition, in FIGS. 6 to 8, the +Z direction is shown as a downward direction in the drawings. In addition, in FIGS. 9 and 10, the +Z direction is shown as an upward direction in the drawings.

First, for example, a fifth layer 58 is formed on the surface 18a of the substrate 18. Then, a first layer 52 is formed on the fifth layer 58. Then, a second layer 54 is formed on the first layer 52. Then, a third layer 56 is formed on the second layer 54 (FIG. 6). In addition, the fifth layer 58, the first layer 52, the second layer 54, and the third layer 56 are formed by, for example, CVD.

Then, an opening H1 is formed which penetrates the third layer 56, the second layer 54, and the first layer 52 to reach the fifth layer 58. In addition, the opening H1 is formed by, for example, RIE.

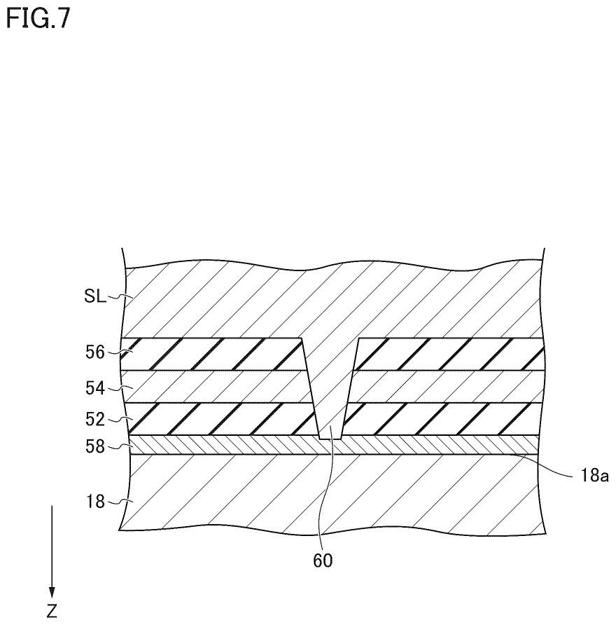

Then, the source line SL is formed on the third layer 56. In addition, a first columnar portion 60 (an example of a columnar portion) that is electrically connected to the source line SL and has an electrical conductivity is formed in the opening H1 (FIG. 7). In addition, the source line SL and the first columnar portion 60 are formed by, for example, CVD.

As a result, the first layer 52 is provided on the surface 18a. The second layer 54 is provided on the first layer 52. The third layer 56 is provided on the second layer 54. The fifth layer 58 is disposed between the surface 18a and the first layer 52.

The substrate 18 allows laser light to pass therethrough. For example, when the substrate 18 is a silicon substrate, a CO₂ laser is preferably used as a laser. The wavelength of the CO₂ laser is, for example, 9.2μm or more and 10.8μm or less. In addition, the combination of the substrate 18 and the laser is not limited to the above.

The second layer 54 is a layer that has a higher laser light absorption rate than the first layer 52 and the third layer 56 and has a higher thermal conductivity than the first layer 52 and the third layer 56. The first layer 52 and the third layer 56 are layers that have a lower laser light absorption rate than the second layer 54 and have a lower thermal conductivity than the second layer 54. The thermal conductivity of the first layer 52 is preferably 1/10 or less of the thermal conductivity of the second layer 54.

As the first layer 52 and the third layer 56, for example, a layer containing silicon oxide is used. In addition, the first layer 52 and the third layer 56 may contain other insulating materials, such as silicon nitride.

For example, a case is considered in which the second layer 54 is not provided and the first layer 52 or the third layer 56 is provided between the source line SL and the surface 18a. In this case, when laser light is emitted onto the surface 18b to peel off the substrate 18, the laser light is absorbed by the first layer 52 or the third layer 56 through the substrate 18, so that the substrate 18 is thermally deformed and peeled off. At this time, damage such as lattice defects may occur on the surface 18a of the substrate 18. Here, it is preferable that the peeled substrate 18 is reused to form the device layer 91 again. However, when the surface 18a is damaged, there is a problem in that such reuse becomes difficult.

In order to prevent this, the second layer 54 is provided, which has a higher laser light absorption rate than the first layer 52 and the third layer 56 and a higher thermal conductivity than the first layer 52 and the third layer 56. In this case, laser light is absorbed by the second layer 54, causing the second layer 54 to thermally expand. Then, a crack occurs at the interface between the second layer 54 and the first layer 52, so that damage to the substrate 18 is suppressed and the substrate 18 can be peeled off.

The second layer 54 preferably contains, for example, polysilicon. Polysilicon has a higher thermal conductivity and a larger average coefficient of thermal expansion than silicon oxide or silicon nitride. Therefore, the heat generated by the laser light is likely to be transmitted uniformly to the entire second layer 54, which makes it easier for a crack to occur between the first layer 52 and the second layer 54.

The film thickness of the first layer 52 is preferably 20 nm or more and 100 nm or less. The thickness of the second layer 54 is preferably 100 nm or more and 500 nm or less.

The first columnar portion 60 has an electrical conductivity, and electrically connects the source line SL and the substrate 18 to each other. During the semiconductor device manufacturing process, “arcing” can occur in which a large current is instantaneously discharged through an insulator or the air. In order to suppress damage to devices such as memory cells due to this “arcing”, the first columnar portion 60 is provided. As a result, a large current generated by discharge from the device through the first columnar portion 60 flows to the substrate 18 through the fifth layer 58 described below. Therefore, damage to the device is suppressed.

The first columnar portion 60 preferably contains, for example, polysilicon. In addition, for example, the source line SL and the first columnar portion 60 may be formed simultaneously using polysilicon by, for example, CVD.

In addition, in FIG. 7, the first columnar portion 60 has a shape whose diameter or cross sectional area decreases from the third layer 56 side to the substrate 18 side. However, the first columnar portion 60 may have a shape, for example, whose diameter or cross sectional area increases from the third layer 56 side to the substrate 18 side. Thus, the shape of the first columnar portion 60 is not limited to that shown in FIG. 7.

The fifth layer 58 is a layer that has an electrical conductivity and allows laser light to pass therethrough (through which laser light can pass). The fifth layer 58 preferably contains, for example, silicon and germanium. The fifth layer 58 preferably contains silicon in an amount of 40 at % or more and 60 at % or less and germanium in an amount of 10 at % or more and 60 at % or less. In addition, the fifth layer 58 may have an electrical conductivity by containing an organic conductive film such as polyaniline or a derivative thereof, polypyrrole or a derivative thereof, polythiophene or a derivative thereof, or PEDOT-PSS (poly (3,4-ethylene-dioxythiopherene-poly)).

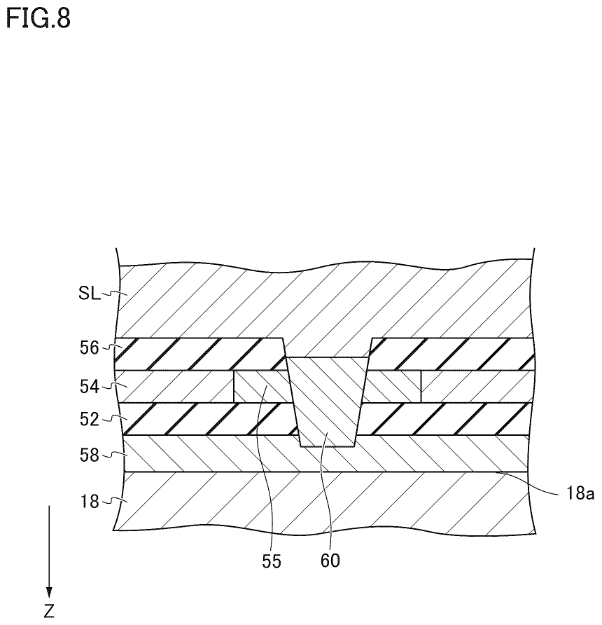

When the device is heated to form devices in the device layer 91, for example, germanium in the fifth layer 58 is diffused into the polysilicon of the first columnar portion 60 and into the polysilicon of the second layer 54 (FIG. 8). A portion 55 in which germanium is diffused within the second layer 54 is also shown in FIG. 8.

Then, the device layer 91 and the circuit layer 92 are bonded together, and laser light is emitted onto the surface 18b to peel off the substrate 18 (FIG. 9).

Then, a part of the second layer 54 on the third layer 56 and a part of the first columnar portion 60 are removed by, for example, CMP (FIG. 10).

Next, the function and effect of the semiconductor device manufacturing method and the semiconductor device of embodiments will be described.

As described above, even if the second layer 54 is provided, when the fifth layer 58 is not provided and the surface 18a of the substrate 18 is in direct contact with the first columnar portion 60, there is a problem in that the surface 18a is damaged at a portion where the surface 18a and the first columnar portion 60 are in contact with each other.

By providing the fifth layer 58, it is possible to prevent the first columnar portion 60 from coming into direct contact with the surface 18a or to prevent a part of the first columnar portion 60 from being provided within the substrate 18. In addition, since the fifth layer 58 has an electrical conductivity, the flow of current from the first columnar portion 60 to the substrate 18 is not hindered. In addition, since the fifth layer 58 allows laser light to pass therethrough, heating of the second layer 54 by the laser light is not hindered. Therefore, damage to the substrate 18 is suppressed, making it easier to reuse the substrate 18.

The fifth layer preferably contains silicon in an amount of 40 at % or more and 90 at % or less and germanium in an amount of 10 at % or more and 60 at % or less. This is because if the ratio of germanium is less than 10 at %, the frequency characteristics deteriorate, whereas if the ratio of germanium is more than 60 at %, controllability such as lattice mismatch deteriorates.

The thermal conductivity of the first layer 52 is preferably 1/10 or less of the thermal conductivity of the second layer 54. This is because a crack is likely to occur at the interface between the first layer 52 and the second layer 54 because the second layer 54 conducts heat better than the first layer 52 and the second layer 54 thermally expands more easily than the first layer 52, and accordingly, the substrate 18 can be easily peeled off.

The film thickness of the first layer 52 is preferably 20 nm or more and 100 nm or less. This is because when the film thickness of the first layer 52 is less than 20 nm, the first layer 52 is too thin, and accordingly, a crack in the first layer 52 may cause damage to the surface 18a. On the other hand, this is because when the film thickness of the first layer 52 is larger than 100 nm, the first layer 52 is too thick, and accordingly, the laser light may not be transmitted satisfactorily up to the second layer 54.

The thickness of the second layer 54 is preferably 100 nm or more and 500 nm or less. This is because when the film thickness of the second layer 54 is less than 100 nm, the second layer 54 is too thin, and accordingly, the laser light may be transmitted up to the third layer 56 to cause the second layer 54 to be not heated sufficiently. On the other hand, this is because when the film thickness of the second layer 54 is larger than 500 nm, the second layer 54 is too thick, and accordingly, the heating by the laser light may not be uniform across the entire second layer 54 to cause the substrate 18 to be not peeled off satisfactorily.

According to embodiments, it is possible to provide a semiconductor device manufacturing method and a semiconductor device using a bonding technique for bonding substrates together, which allows easy reuse of substrates.

### Second Embodiment

A semiconductor device manufacturing method of embodiments includes: forming, for a stacked body having a first substrate allowing laser light to pass therethrough and the first substrate having a first surface and a second surface, a first layer provided on the first surface, a second layer provided on the first layer, the second layer having a higher absorption rate for the laser light than the first layer, and the second layer having a higher thermal conductivity than the first layer, and a third layer provided on the second layer, the third layer having a lower absorption rate for the laser light than the second layer, and the third layer having a lower thermal conductivity than the second layer, an opening penetrating the third layer, the second layer, and the first layer; forming a first film on a side surface of the first layer, a side surface of the second layer, and a side surface of the third layer in the opening, and the first film containing a different material from the first layer, the second layer, and the third layer; forming a columnar portion having an electrical conductivity in the opening and forming a fourth layer on the third layer, the fourth layer being electrically connected to the columnar portion, and the fourth layer having an electrical conductivity; forming a sixth layer on the fourth layer, the sixth layer having a device electrically connected to the fourth layer; bonding the sixth layer to a seventh layer, the seventh layer being provided on a third surface of a second substrate, the second substrate having the third surface and a fourth surface, and the seventh layer having an electrical circuit; emitting the laser light onto the second surface; and peeling off the first substrate.

A semiconductor device of embodiments includes: a second substrate having a third surface and a fourth surface; a seventh layer provided on the third surface and the seventh layer having an electrical circuit; a sixth layer provided on the seventh layer and the sixth layer having a device; a fourth layer provided on the sixth layer, the fourth layer being electrically connected to the device, and the fourth layer having an electrical conductivity; a third layer provided on the fourth layer; a columnar portion penetrating the third layer, the columnar portion being electrically connected to the fourth layer, and the columnar portion having an electrical conductivity; and a first film provided between the columnar portion and the third layer and the first film containing a different material from the third layer.

Here, the description of the content overlapping the first embodiment will be omitted.

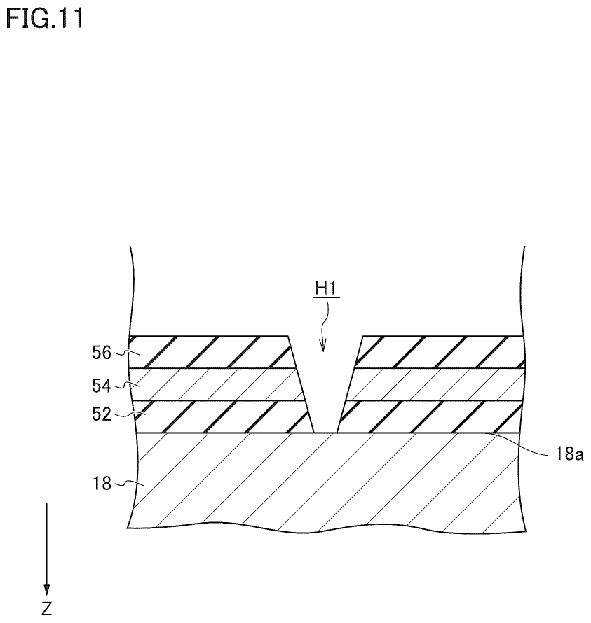

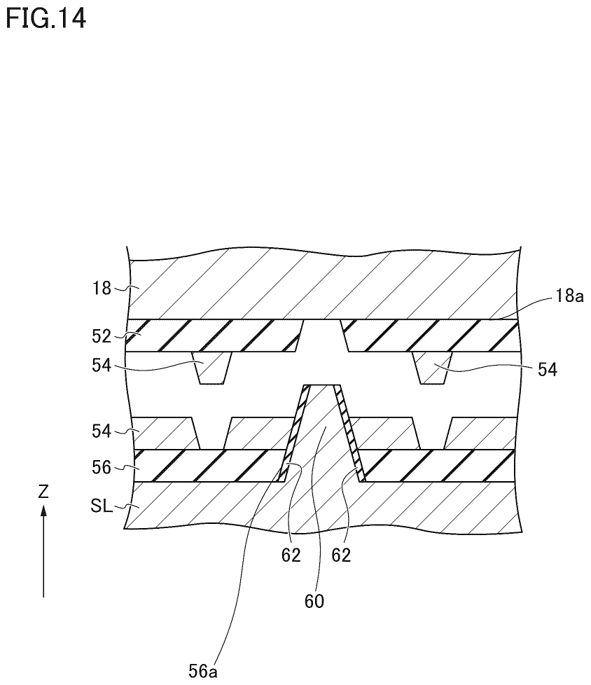

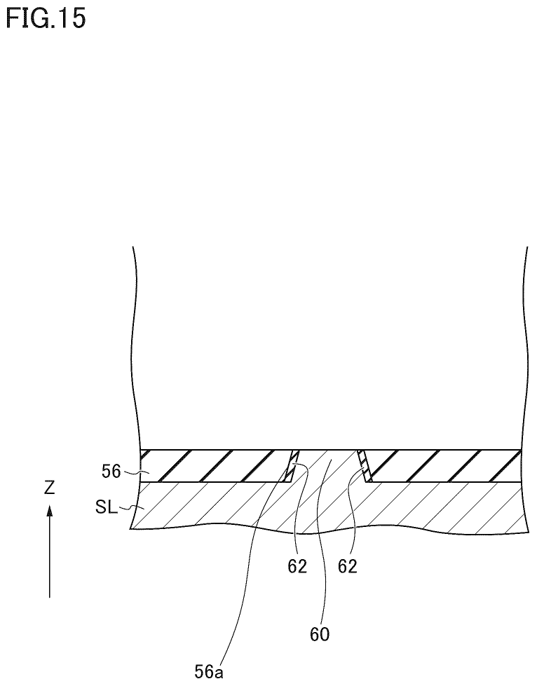

FIGS. 11 to 15 are schematic cross-sectional views showing a method for manufacturing a main portion (an example of a stacked body) of the semiconductor device of embodiments. In addition, in FIGS. 11 to 13, the +Z direction is shown as a downward direction in the drawings. In addition, in FIGS. 14 and 15, the +Z direction is shown as an upward direction in the drawings.

A first layer 52 is formed on a surface 18a of a substrate 18. Then, a second layer 54 is formed on the first layer 52. Then, a third layer 56 is formed on the second layer 54. In embodiments, the fifth layer 58 is not provided. Then, an opening H1 is formed which penetrates the third layer 56, the second layer 54, and the first layer 52 to reach the substrate 18 (FIG. 11).

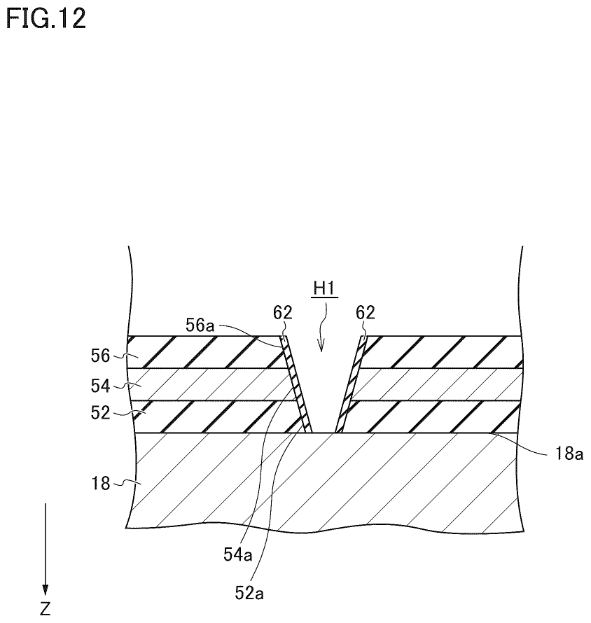

Then, a first film 62 is formed on a side surface 52a of the first layer, a side surface 54a of the second layer, and a side surface 56a of the third layer by, for example, CVD and etchback. The first film 62 contains a different material from the first layer 52, the second layer 54, and the third layer 56 (FIG. 12).

The first film 62 preferably contains, for example, silicon, carbon, and nitrogen. The first film 62 preferably contains, for example, silicon carbonitride. The first film 62 is preferably, for example, a SiCN film.

Alternatively, the first film 62 preferably contains, for example, silicon and nitrogen. The first film 62 preferably contains, for example, silicon nitride. The first film 62 is preferably, for example, a SiN film.

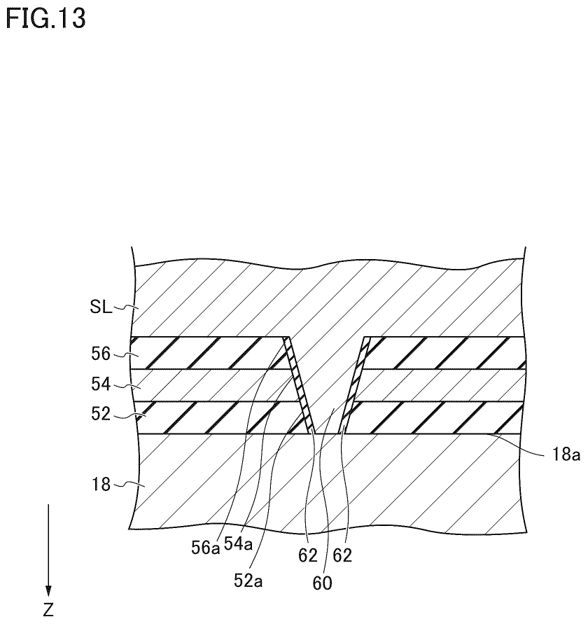

Then, a source line SL having an electrical conductivity is formed on the third layer 56. In addition, a first columnar portion 60 that is electrically connected to the source line SL and has an electrical conductivity is formed in the opening H1 (FIG. 13).

Then, a device layer 91 and a circuit layer 92 are bonded together, and laser light is emitted onto the surface 18b to peel off the substrate 18 (FIG. 14).

Then, a part of the second layer 54 on the third layer 56, a part of the first columnar portion 60, and a part of the first film 62 between the third layer 56 and the first columnar portion 60 are removed by, for example, CMP. As a result, the first columnar portion 60 provided in the third layer 56 and the first film 62 provided between the third layer 56 and the first columnar portion 60 remain (FIG. 15).

The other steps are similar to those in the first embodiment.

The first film 62 is likely to be peeled off from the substrate 18 and the first layer 52 when stress due to the peeling of the substrate 18 is applied. This is because the first film 62 contains a different material from the first layer 52, the second layer 54, and the third layer 56. Therefore, the substrate 18 is less likely to be damaged by the first columnar portion 60. In particular, when the first layer 52 contains silicon oxide, the first film 62 preferably contains silicon, carbon, and nitrogen. Alternatively, the first film 62 preferably contains silicon and nitrogen.

According to embodiments as well, it is possible to provide a semiconductor device manufacturing method and a semiconductor device using a bonding technique for bonding substrates together, which allows easy reuse of substrates.

### Third Embodiment

A semiconductor device manufacturing method of embodiments includes: forming, for a first substrate allowing laser light to pass therethrough and the first substrate having a first surface and a second surface, and a second substrate having a first layer provided on the first surface, a second layer provided on the first layer, the second layer having a higher absorption rate for the laser light than the first layer, and the second layer having a higher thermal conductivity than the first layer, and a third layer provided on the second layer, the third layer having a lower absorption rate for the laser light than the second layer, and the third layer having a lower thermal conductivity than the second layer, an opening penetrating the third layer, the second layer, and the first layer; forming a columnar portion having an electrical conductivity in the opening; forming a fourth layer on the third layer and the columnar portion, the fourth layer having an electrical conductivity, and the fourth layer containing a different material from the columnar portion; forming a sixth layer on the fourth layer, the sixth layer having a device electrically connected to the fourth layer; bonding the sixth layer to a seventh layer of a fourth substrate, the fourth substrate having a third substrate having a third surface and a fourth surface, and the seventh layer provided on the third surface and having an electrical circuit; emitting the laser light onto the second surface; and peeling off the first substrate.

Here, the description of the content overlapping the first and second embodiments will be omitted.

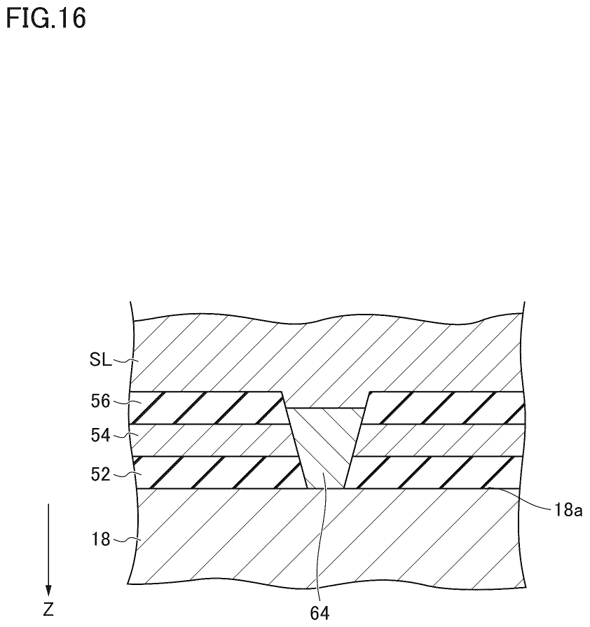

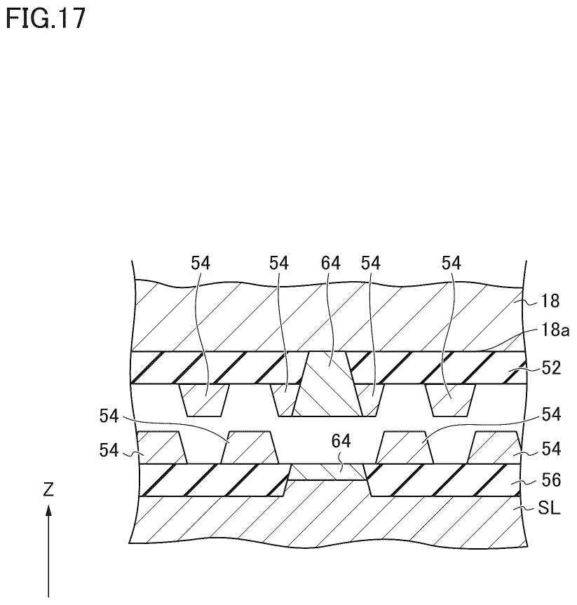

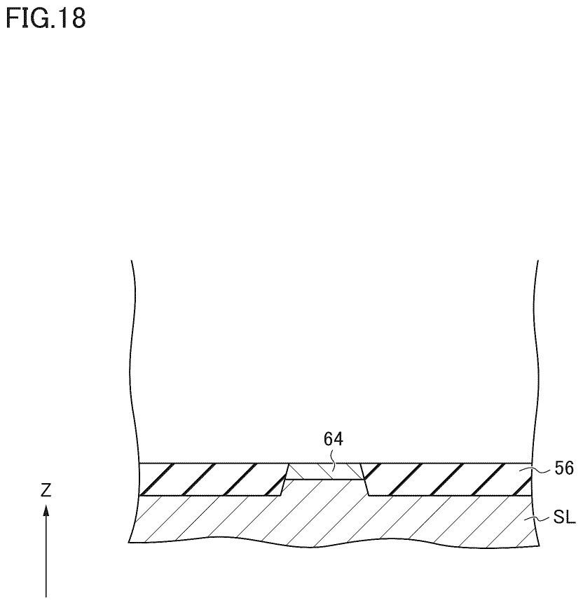

FIGS. 16 to 18 are schematic cross-sectional views showing a method for manufacturing a main portion (an example of a stacked body) of the semiconductor device of embodiments. In addition, in FIG. 16, the +Z direction is shown as a downward direction in the drawings. In addition, in FIGS. 17 and 18, the +Z direction is shown as an upward direction in the drawings.

In embodiments, after forming an opening H1 that penetrates a third layer 56, a second layer 54, and a first layer 52 to reach a substrate 18, a second columnar portion 64 (an example of a columnar portion) containing single crystal silicon is formed, for example, by epitaxially growing silicon. Then, a source line SL is formed on the third layer 56 and the second columnar portion 64. The source line SL and the substrate 18 are electrically connected to each other by the second columnar portion 64 (FIG. 16).

Then, a device layer 91 and a circuit layer 92 are bonded together, and laser light is emitted onto the surface 18b to peel off the substrate 18 (FIG. 17).

Then, a part of the second layer 54 on the third layer 56 and a part of the second columnar portion 64 are removed by, for example, CMP. As a result, a part of the second columnar portion 64 remains in the third layer 56 (FIG. 18).

In addition, in FIG. 17, the second columnar portion 64 has a shape whose diameter or cross sectional area decreases from the third layer 56 side to the substrate 18 side. However, the shape of the second columnar portion 64 is not limited to that shown in FIG. 17.

The other steps are similar to those in the first and second embodiments.

In the first and second embodiments, the contact portion between polysilicon and silicon is the interface between the first columnar portion 60 and the substrate 18. For this reason, the polysilicon contained in the first columnar portion 60 generates heat due to the laser. On the other hand, in embodiments, the contact portion between polysilicon and silicon is the interface between the second columnar portion 64 and the source line SL. This makes it possible to increase the distance between the substrate 18 and the polysilicon that absorbs the laser and generates heat. Therefore, stress is less likely to be applied directly to the substrate 18 during peeling. As a result, damage to the substrate 18 can be suppressed.

According to embodiments as well, it is possible to provide a semiconductor device manufacturing method and a semiconductor device using a bonding technique for bonding substrates together, which allows easy reuse of substrates.

### Fourth Embodiment

A semiconductor device manufacturing method of embodiments includes: forming, for a stacked body having a first substrate allowing laser light to pass therethrough and the first substrate having a first surface, a second surface, and a protrusion provided on the first surface, a first layer provided on the first surface and the protrusion, a second layer provided on the first layer, the second layer having a higher absorption rate for the laser light than the first layer, and the second layer having a higher thermal conductivity than the first layer, and a third layer provided on the second layer, the third layer having a lower absorption rate for the laser light than the second layer, and the third layer having a lower thermal conductivity than the second layer, an opening penetrating the third layer, the second layer, and the first layer to reach the protrusion; forming a columnar portion having an electrical conductivity in the opening and forming a fourth layer on the third layer, the fourth layer being electrically connected to the columnar portion, and the fourth layer having an electrical conductivity; forming a sixth layer on the fourth layer, the sixth layer having a device electrically connected to the fourth layer; bonding the sixth layer to a seventh layer provided on a third surface of a second substrate, the second substrate having the third surface and a fourth surface, and the seventh layer having an electrical circuit; emitting the laser light onto the second surface; and peeling off the first substrate.

Here, the description of the content overlapping the first to third embodiments will be omitted.

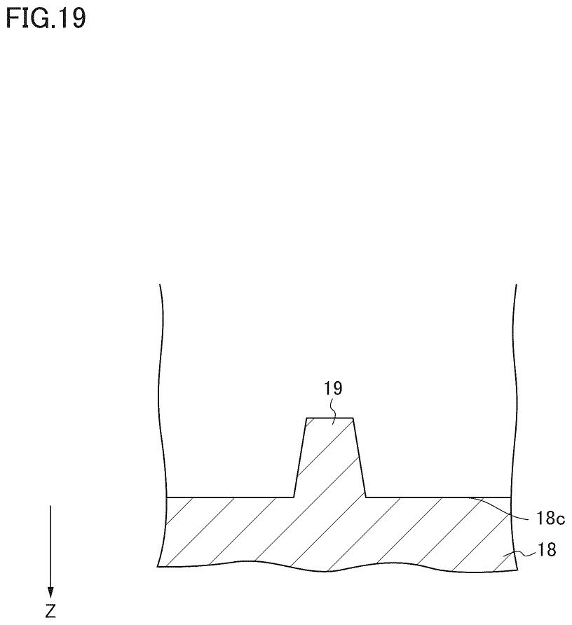

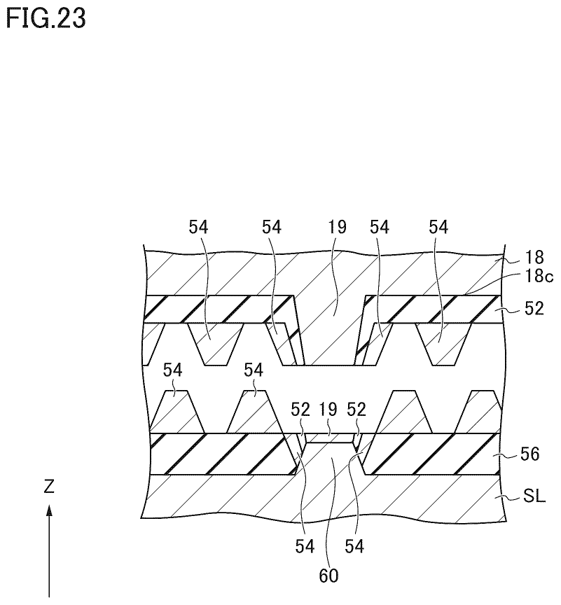

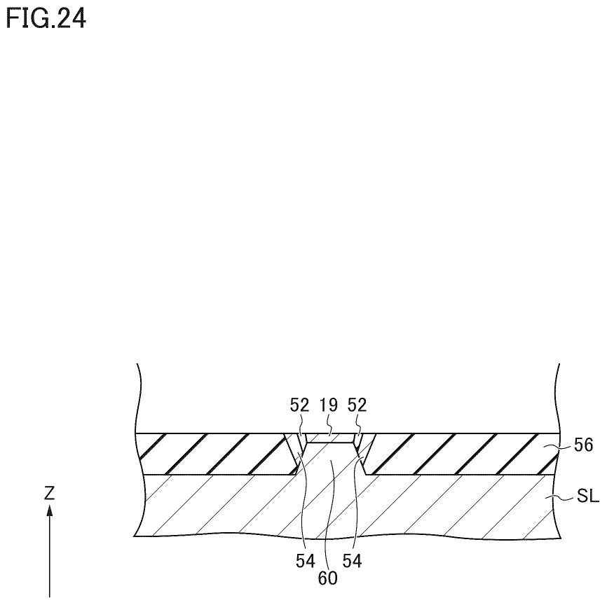

FIGS. 19 to 24 are schematic cross-sectional views showing a method for manufacturing a main portion (an example of a stacked body) of the semiconductor device of embodiments. In addition, in FIGS. 19 to 22, the +Z direction is shown as a downward direction in the drawings. In addition, in FIGS. 23 and 24, the +Z direction is shown as an upward direction in the drawings.

A protrusion 19 is formed on a substrate 18 by, for example, photolithography. For example, a part of the substrate 18 including a surface 18a is removed to form the protrusion 19 on a surface 18c (an example of a first surface) (FIG. 19).

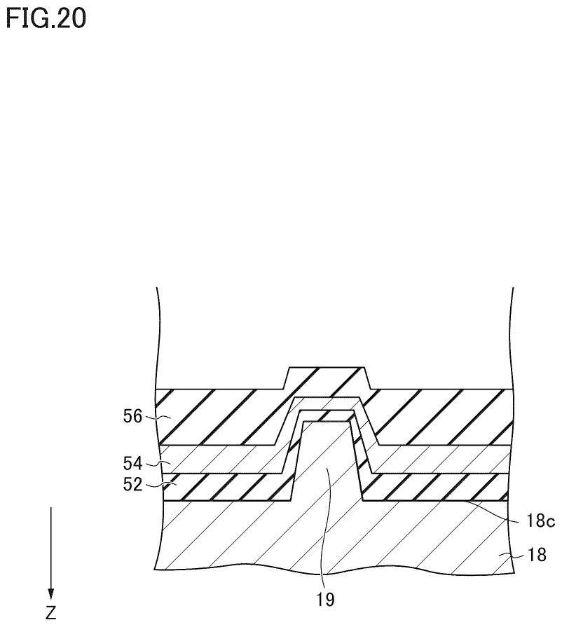

Then, a first layer 52 is formed on the surface 18c and the protrusion 19. Then, a second layer 54 is formed on the first layer 52. Then, a third layer 56 is formed on the second layer 54 (FIG. 20).

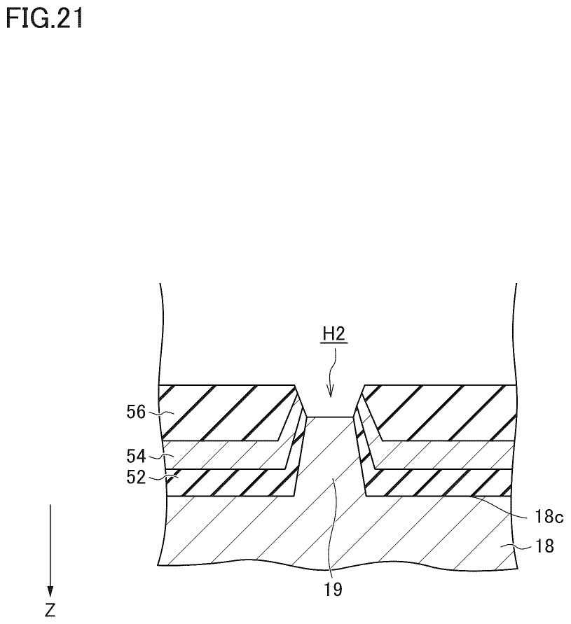

Then, an opening H2 is formed which penetrates the third layer 56, the second layer 54, and the first layer 52 to reach the protrusion 19 (FIG. 21).

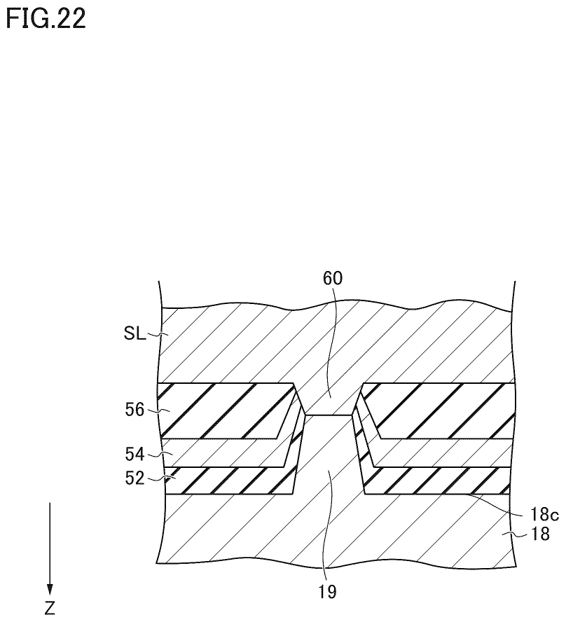

Then, a source line SL is formed on the third layer 56. In addition, a first columnar portion 60 that is electrically connected to the source line SL and has an electrical conductivity is formed in the opening H2 (FIG. 22).

Then, a device layer 91 and a circuit layer 92 are bonded together, and laser light is emitted onto the surface 18b to peel off the substrate 18 (FIG. 23).

Then, a part of the second layer 54, a part of the first layer 52, or a part of the protrusion 19 remaining on the third layer 56 is removed by, for example, CMP (FIG. 24). The first columnar portion 60, a part of the protrusion 19, a part of the first layer 52, or a part of the second layer 54 may remain in the third layer 56.

The other steps are similar to those in the first to third embodiments.

In the first and second embodiments, the contact portion between polysilicon and silicon is the interface between the first columnar portion 60 and the substrate 18. For this reason, the polysilicon contained in the first columnar portion 60 generates heat due to the laser. On the other hand, in embodiments, since the protrusion 19 is provided, it is possible to increase the distance between the surface 18c and the first columnar portion 60 that contains polysilicon and generates heat by laser. Therefore, stress is less likely to be applied directly to the substrate 18 during peeling. As a result, damage to the substrate 18 can be suppressed.

According to embodiments as well, it is possible to provide a semiconductor device manufacturing method and a semiconductor device using a bonding technique for bonding substrates together, which allows easy reuse of substrates.

While embodiments have been described, embodiments are presented as examples, and it is not intended to limit the scope of the inventions. Embodiments can be implemented in various other forms, and various omissions, replacements, and modifications can be made without departing from the scope of the inventions. Embodiments or their modifications are included in the scope or gist of the inventions, and are included in the scope of the inventions described in the claims and their equivalents.

In addition, embodiments described above can be summarized as the following technical proposals.

### Technical Proposal 1

A semiconductor device manufacturing method, including:
forming, for a stacked body having
   a first substrate allowing laser light to pass therethrough and the first substrate having a first surface and a second surface,
   a first layer provided on the first surface,
   a second layer provided on the first layer, the second layer having a higher absorption rate for the laser light than the first layer, and the second layer having a higher thermal conductivity than the first layer,
   a third layer provided on the second layer, the third layer having a lower absorption rate for the laser light than the second layer, and the third layer having a lower thermal conductivity than the second layer, and
   a fifth layer provided between the first layer and the first substrate and the fifth layer having an electrical conductivity,
an opening penetrating the third layer, the second layer, and the first layer to reach the fifth layer;
forming a columnar portion and a fourth layer, the columnar portion being provided in the opening, the columnar portion having an electrical conductivity, the fourth layer being provided on the third layer, the fourth layer being electrically connected to the columnar portion, and the fourth layer having an electrical conductivity;
forming a sixth layer on the fourth layer, the sixth layer having a device, and the device being electrically connected to the fourth layer;
bonding the sixth layer to a seventh layer, the seventh layer being provided on a third surface of a second substrate, the second substrate having the third surface and a fourth surface, and the seventh layer having an electrical circuit;
emitting the laser light onto the second surface; and peeling off the first substrate.

### Technical Proposal 2

The semiconductor device manufacturing method according to Technical Proposal 1,
wherein the first substrate is a silicon substrate,
the first layer contains silicon and oxygen,
the second layer contains polysilicon,
the third layer contains silicon and oxygen,
the fourth layer and the columnar portion contain polysilicon, and
the fifth layer contains silicon and germanium.

### Technical Proposal 3

The semiconductor device manufacturing method according to Technical Proposal 1,
wherein, when the sixth layer is formed, germanium in the fifth layer is diffused into the columnar portion and the second layer.

### Technical Proposal 4

The semiconductor device manufacturing method according to Technical Proposal 1,
wherein the fifth layer contains silicon in an amount of 40 at % or more and 90 at % or less and germanium in an amount of 10 at % or more and 60 at % or less.

### Technical Proposal 5

The semiconductor device manufacturing method according to Technical Proposal 1,
wherein a film thickness of the first layer is 20 nm or more and 100 nm or less.

### Technical Proposal 6

The semiconductor device manufacturing method according to Technical Proposal 1,
wherein a film thickness of the second layer is 100 nm or more and 500 nm or less.

### Technical Proposal 7

The semiconductor device manufacturing method according to Technical Proposal 1,
wherein a thermal conductivity of the first layer is 1/10 or less of a thermal conductivity of the second layer.

### Technical Proposal 8

The semiconductor device manufacturing method according to Technical Proposal 1,
wherein the laser light is emitted using a CO₂ laser.

In addition, embodiments described above can be summarized as the following technical proposals.

### Technical Proposal 9

A semiconductor device manufacturing method, including:
forming, for a stacked body having
   a first substrate allowing laser light to pass therethrough and the first substrate having a first surface and a second surface,
   a first layer provided on the first surface,
   a second layer provided on the first layer, the second layer having a higher absorption rate for the laser light than the first layer, and the second layer having a higher thermal conductivity than the first layer, and
   a third layer provided on the second layer, the third layer having a lower absorption rate for the laser light than the second layer, and the third layer having a lower thermal conductivity than the second layer,
an opening penetrating the third layer, the second layer, and the first layer;
forming a first film on a side surface of the first layer, a side surface of the second layer, and a side surface of the third layer in the opening, and the first film containing a different material from the first layer, the second layer, and the third layer;
forming a columnar portion having an electrical conductivity in the opening and forming a fourth layer on the third layer, the fourth layer being electrically connected to the columnar portion, and the fourth layer having an electrical conductivity;
forming a sixth layer on the fourth layer, the sixth layer having a device electrically connected to the fourth layer;
bonding the sixth layer to a seventh layer, the seventh layer being provided on a third surface of a second substrate, the second substrate having the third surface and a fourth surface, and the seventh layer having an electrical circuit;
emitting the laser light onto the second surface; and
peeling off the first substrate.

### Technical Proposal 10

The semiconductor device manufacturing method according to Technical Proposal 9,
wherein the first substrate is a silicon substrate,
the first layer contains silicon and oxygen,
the second layer contains polysilicon,
the third layer contains silicon and oxygen,
the fourth layer and the columnar portion contain polysilicon, and
the first film contains nitrogen and silicon.

### Technical Proposal 11

The semiconductor device manufacturing method according to Technical Proposal 10,
wherein the first film further contains carbon.

### Technical Proposal 12

The semiconductor device manufacturing method according to Technical Proposal 9,
wherein a film thickness of the first layer is 20 nm or more and 100 nm or less.

### Technical Proposal 13

The semiconductor device manufacturing method according to Technical Proposal 9,
wherein a film thickness of the second layer is 100 nm or more and 500 nm or less.

### Technical Proposal 14

The semiconductor device manufacturing method according to Technical Proposal 9,
wherein a thermal conductivity of the first layer is 1/10 or less of a thermal conductivity of the second layer.

### Technical Proposal 15

The semiconductor device manufacturing method according to Technical Proposal 9,
wherein the laser light is emitted using a CO₂ laser.

In addition, embodiments described above can be summarized as the following technical proposals.

### Technical Proposal 16

A semiconductor device, including:
a second substrate having a third surface and a fourth surface;
a seventh layer provided on the third surface and the seventh layer having an electrical circuit;
a sixth layer provided on the seventh layer and the sixth layer having a device;
a fourth layer provided on the sixth layer, the fourth layer being electrically connected to the device, and the fourth layer having an electrical conductivity;
a third layer provided on the fourth layer;
a columnar portion penetrating the third layer, the columnar portion being electrically connected to the fourth layer, and the columnar portion having an electrical conductivity; and
a first film provided between the columnar portion and the third layer and the first film containing a different material from the third layer.

### Technical Proposal 17

The semiconductor device according to Technical Proposal 16,
wherein the third layer contains silicon and oxygen,
the fourth layer and the columnar portion contain polysilicon, and
the first film contains nitrogen and silicon.

In addition, embodiments described above can be summarized as the following technical proposals.

### Technical Proposal 18

A semiconductor device manufacturing method, including:
forming, for
   a first substrate allowing laser light to pass therethrough and the first substrate having a first surface and a second surface, and
   a second substrate having
      a first layer provided on the first surface,
      a second layer provided on the first layer, the second layer having a higher absorption rate for the laser light than the first layer, and the second layer having a higher thermal conductivity than the first layer, and
      a third layer provided on the second layer, the third layer having a lower absorption rate for the laser light than the second layer, and the third layer having a lower thermal conductivity than the second layer,
an opening penetrating the third layer, the second layer, and the first layer;
forming a columnar portion having an electrical conductivity in the opening;
forming a fourth layer on the third layer and the columnar portion, the fourth layer having an electrical conductivity, and the fourth layer containing a different material from the columnar portion;
forming a sixth layer on the fourth layer, the sixth layer having a device electrically connected to the fourth layer;
bonding the sixth layer to a seventh layer of a fourth substrate, the fourth substrate having
   a third substrate having a third surface and a fourth surface, and
   the seventh layer provided on the third surface and having an electrical circuit;
emitting the laser light onto the second surface; and peeling off the first substrate.

### Technical Proposal 19

The semiconductor device manufacturing method according to Technical Proposal 18,
wherein the first substrate is a silicon substrate,
the first layer contains silicon and oxygen,
the second layer contains polysilicon,
the third layer contains silicon and oxygen,
the fourth layer contains polysilicon, and
the columnar portion contains single crystal silicon.

In addition, embodiments described above can be summarized as the following technical proposals.

### Technical Proposal 20

A semiconductor device manufacturing method, including:
forming, for a stacked body having
   a first substrate allowing laser light to pass therethrough and the first substrate having a first surface, a second surface, and a protrusion provided on the first surface,
   a first layer provided on the first surface and the protrusion,
   a second layer provided on the first layer, the second layer having a higher absorption rate for the laser light than the first layer, and the second layer having a higher thermal conductivity than the first layer, and
   a third layer provided on the second layer, the third layer having a lower absorption rate for the laser light than the second layer, and the third layer having a lower thermal conductivity than the second layer,
an opening penetrating the third layer, the second layer, and the first layer to reach the protrusion;
forming a columnar portion having an electrical conductivity in the opening and forming a fourth layer on the third layer, the fourth layer being electrically connected to the columnar portion, and the fourth layer having an electrical conductivity;
forming a sixth layer on the fourth layer, the sixth layer having a device electrically connected to the fourth layer;
bonding the sixth layer to a seventh layer provided on a third surface of a second substrate, the second substrate having the third surface and a fourth surface, and the seventh layer having an electrical circuit;
emitting the laser light onto the second surface; and
peeling off the first substrate.

### Technical Proposal 21

The semiconductor device manufacturing method according to Technical Proposal 20,
wherein the first substrate is a silicon substrate,
the first layer contains silicon and oxygen,
the second layer contains polysilicon,
the third layer contains silicon and oxygen, and
the fourth layer and the columnar portion contain polysilicon.

While certain embodiments have been described, these embodiments have been presented by way of example only, and are not intended to limit the scope of the inventions. Indeed, the semiconductor device manufacturing method and the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device manufacturing method, comprising:
forming, for a stacked body having
a first substrate allowing laser light to pass therethrough and the first substrate having a first surface and a second surface,
a first layer provided on the first surface,
a second layer provided on the first layer, the second layer having a higher absorption rate for the laser light than the first layer, and the second layer having a higher thermal conductivity than the first layer,
a third layer provided on the second layer, the third layer having a lower absorption rate for the laser light than the second layer, and the third layer having a lower thermal conductivity than the second layer, and
a fifth layer provided between the first layer and the first substrate and the fifth layer having an electrical conductivity,
an opening penetrating the third layer, the second layer, and the first layer to reach the fifth layer;
forming a columnar portion and a fourth layer, the columnar portion being provided in the opening, the columnar portion having an electrical conductivity, the fourth layer being provided on the third layer, the fourth layer being electrically connected to the columnar portion, and the fourth layer having an electrical conductivity;
forming a sixth layer on the fourth layer, the sixth layer having a device, and the device being electrically connected to the fourth layer;
bonding the sixth layer to a seventh layer, the seventh layer being provided on a third surface of a second substrate, the second substrate having the third surface and a fourth surface, and the seventh layer having an electrical circuit;
emitting the laser light onto the second surface; and
peeling off the first substrate.

2. The semiconductor device manufacturing method according to claim 1,
wherein the first substrate is a silicon substrate,
the first layer contains silicon and oxygen,
the second layer contains polysilicon,
the third layer contains silicon and oxygen,
the fourth layer and the columnar portion contain polysilicon, and
the fifth layer contains silicon and germanium.

3. The semiconductor device manufacturing method according to claim 1,
wherein, when the sixth layer is formed, germanium in the fifth layer is diffused into the columnar portion and the second layer.

4. The semiconductor device manufacturing method according to claim 1,
wherein the fifth layer contains silicon in an amount of 40 at % or more and 90 at % or less and germanium in an amount of 10 at % or more and 60 at % or less.

5. The semiconductor device manufacturing method according to claim 1,
wherein a film thickness of the first layer is 20 nm or more and 100 nm or less.

6. The semiconductor device manufacturing method according to claim 1,
wherein a film thickness of the second layer is 100 nm or more and 500 nm or less.

7. The semiconductor device manufacturing method according to claim 1,
wherein a thermal conductivity of the first layer is 1/10 or less of a thermal conductivity of the second layer.

8. The semiconductor device manufacturing method according to claim 1,
wherein the laser light is emitted using a CO₂ laser.

9. A semiconductor device, comprising:
a second substrate having a third surface and a fourth surface;
a seventh layer provided on the third surface and the seventh layer having an electrical circuit;
a sixth layer provided on the seventh layer and the sixth layer having a device;
a fourth layer provided on the sixth layer, the fourth layer being electrically connected to the device, and the fourth layer having an electrical conductivity;
a third layer provided on the fourth layer;
a columnar portion penetrating the third layer, the columnar portion being electrically connected to the fourth layer, and the columnar portion having an electrical conductivity; and
a first film provided between the columnar portion and the third layer and the first film containing a different material from the third layer.

10. The semiconductor device according to claim 9,
wherein the third layer contains silicon and oxygen,
the fourth layer and the columnar portion contain polysilicon, and
the first film contains nitrogen and silicon.

11. A semiconductor device manufacturing method, comprising:
forming, for
a first substrate allowing laser light to pass therethrough and the first substrate having a first surface and a second surface, and
a second substrate having
a first layer provided on the first surface,
a second layer provided on the first layer, the second layer having a higher absorption rate for the laser light than the first layer, and the second layer having a higher thermal conductivity than the first layer, and
a third layer provided on the second layer, the third layer having a lower absorption rate for the laser light than the second layer, and the third layer having a lower thermal conductivity than the second layer,
an opening penetrating the third layer, the second layer, and the first layer;
forming a columnar portion having an electrical conductivity in the opening;
forming a fourth layer on the third layer and the columnar portion, the fourth layer having an electrical conductivity, and the fourth layer containing a different material from the columnar portion;
forming a sixth layer on the fourth layer, the sixth layer having a device electrically connected to the fourth layer;
bonding the sixth layer to a seventh layer of a fourth substrate, the fourth substrate having
a third substrate having a third surface and a fourth surface, and
the seventh layer provided on the third surface and having an electrical circuit;
emitting the laser light onto the second surface; and
peeling off the first substrate.

12. The semiconductor device manufacturing method according to claim 11,
wherein the first substrate is a silicon substrate,
the first layer contains silicon and oxygen,
the second layer contains polysilicon,
the third layer contains silicon and oxygen,
the fourth layer contains polysilicon, and
the columnar portion contains single crystal silicon.
